(19) United States
(12) Patent Application Publication
(10) Pub. No.: US 2004/0232956 A1
(43) Pub. Date: Nov. 25, 2004

(54) Synchronized clocking

(75) Inventors: Huy M. Nguyen, San Jose, CA (US); Benedict C. Lau, San Jose, CA (US); Leung Yu, Santa Clara, CA (US); Jade M. Kizer, Mountain View, CA (US)

Correspondence Address: LEE & HAYES, PLLC, 421 W. RIVERSIDE AVE, STE 500, SPOKANE, WA, 99201, US

(73) Assignee: RAMBUS INC, LOS ALTOS, CA (US)

(21) Appl. No.: 10/443,436

(22) Filed: May 22, 2003

(51) Int. Cl. H03L 7/00

(52) U.S. Cl. 327/141

(57) ABSTRACT

A circuit and method for synchronized clocking of components such as registers. Registers are clocked by individual component clock signals having the same frequency but potentially different phases due to differing propagation delays. A reference clock signal is propagated along a source path and a return path, both of which pass near the registers. At each register, an averaged clock signal is generated, based on the phases of the reference clock signal on the source and return paths. Individual component clock signals are then adjusted separately to minimize differences between the component clock signals and the respective averaged clock signals at each of the registers.

### TECHNICAL FIELD

The invention relates to apparatus and methods for synchronizing clock signals.

### BACKGROUND

Integrated circuits (IC), including application specific integrated circuits (ASIC), are increasing in processing capability and are shrinking in physical size. Decreasing the size of ICs has led to an increase in IC processing speed since communication paths are decreased between IC components.

As IC size decreases, however, resistance-capacitance (RC) time delay of metal interconnects between IC components begins to limit IC performance. Interconnect RC time delay is associated with metal resistance of interconnections and capacitance associated with dielectric media. Because metal resistance and dielectric media are inherently part of the materials used in construction of an IC, only a change in materials will affect (improve) RC time delay. A change in materials may be technically impossible or cost prohibitive.

Differences in propagation delay among various clock paths in a complex IC may lead to unacceptable degradations in overall system-timing. This problem is often referred to as “clock skew.”

FIG. 1 illustrates a clock tree that distributes clock signals in a controlled manner. An IC may contain numerous clocked components requiring clock signals. A clock tree or similar clock architecture provides the necessary clock signals to the components. Components within an IC, specifically registers of the components, may require synchronized clock signals. Synchronized clock signals have the same phase. For example, if two different receivers require clock signals with are synchronized with each other, the clock signal at the first receiver must have the same phase as the clock signal at the second receiver. Synchronizing clock signals which travel over different paths and/or experience different propagation delays can be problematic.

In the particular example depicted in FIG. 1, clock receiving components 10, 15, 20, and 25 reside on a single IC. Components 10, 15,20, and 25 may be at varying distances from one another. In other cases, components 10, 15, 20, and 25 may be equidistant from one another. In this example, components 10, 15, 20, and 25 are components that must be synchronized with one another (i.e., must be clocked by clock signals having the same phase). As mentioned above, components 10, 15, 20, and 25 may be equidistance from each other but may be located at varying distances from a clock source such as clock driver 30. Since clock signals travel over varying distances from the clock source to the components, assuring that each clock signal is in phase with the other clock signals becomes a complicated task. Components 10, 15, 20, and 25 may alternatively be located at varying distances from each other and at varying distances from a clock source. Synchronizing clocks which travel over different paths and/or over different distances can be problematic.

In typical clock architectures such as the clock tree of FIG. 1, a controller such as controller 35 sends a signal to clock driver 30 instructing clock driver 30 to drive a clock signal. Controller 35 can be located on an IC (on-chip) or external to an IC (off-chip). Clock driver 30 may be implemented for example as a clock oscillator or clock generator or similar component. Alternatively, clock driver 30 may be a clock buffer. A clock signal transmitted by clock driver 30 is passed on to fan-out clock drivers 40, 45, 50, 55, 60, and 65. All clock signals derived from clock driver 30 have the same frequency, although clock signals arriving at various components or registers may have different phase values.

Clock drivers 40, 45, 50, 55, 60, and 65 may delay clock signals in order to match a predetermined phase. In other words, a clock driver that receives a clock signal with a phase of 90 degrees, where the proper phase is 180 degrees, may delay the clock signal until the clock signal is at 180 degrees. However, with varying distances from components to clock sources, and components from one another, each clock driver may need to adjust for varying phase delays. Varying lengths result in varying propagation delays and if not compensated, clock skew and other timing related problems can develop.

### BRIEF DESCRIPTION OF THE DRAWINGS

FIG. 1 is a clock tree diagram.

FIG. 2 is a schematic of synchronized components with common clock reference line.

FIG. 3 is a schematic of a register with phase feed-back to a clock driver.

FIG. 4 is a schematic of a phase adjuster that provides an offset value to adjust the phase of a clock driver.

### DETAILED DESCRIPTION

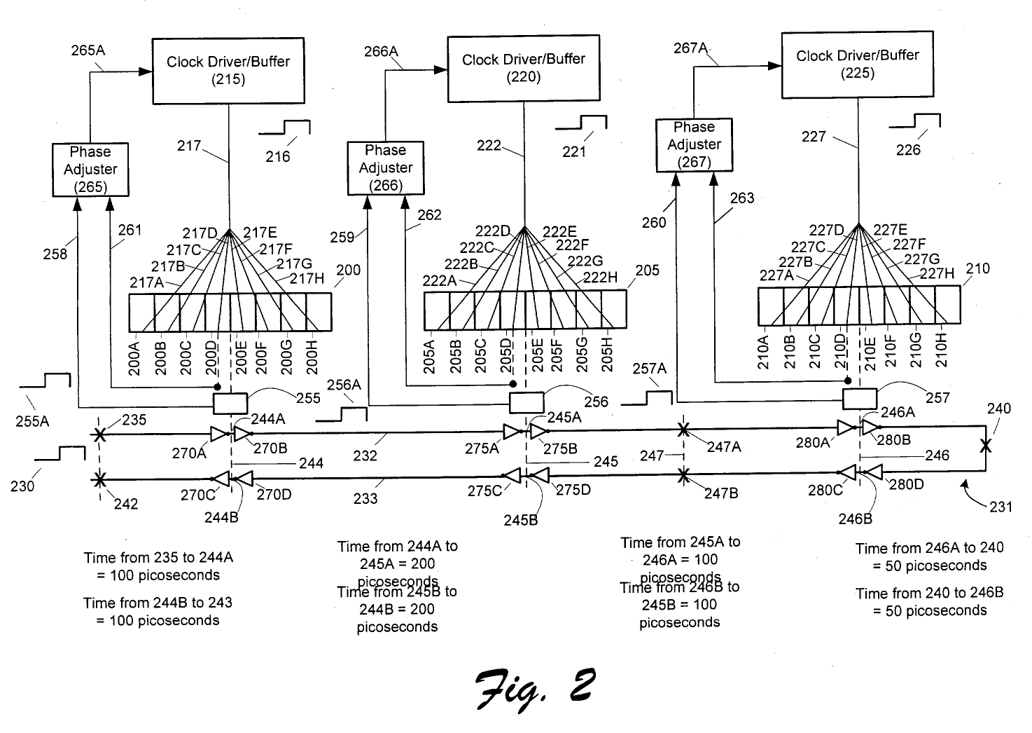

FIG. 2 shows a circuit having a plurality of components. In this example, the components comprise byte-word registers 200, 205, and 210. Byte-word registers 200, 205, and 210 may be part of individual components. The respective components that contain or utilize byte-word registers 200, 205, and 210 may be on the same substrate of an IC. In other cases, components that contain byte-word registers 200, 205, and 210 may be on different substrates of the same IC or on different ICs. Byte-word register 200 is made up of bit registers 200A, 200B, 200C, 200D, 200E, 200F, 200G, and 200H. Byte-word register 205 is made up of bit registers 205A, 205B, 205C, 205D, 200E, 200F, 200G, and 200H. Byte-word register 210 is made up of bit registers 210A, 210B, 210C, 210D, 210E, 210F, 210G, and 210H.

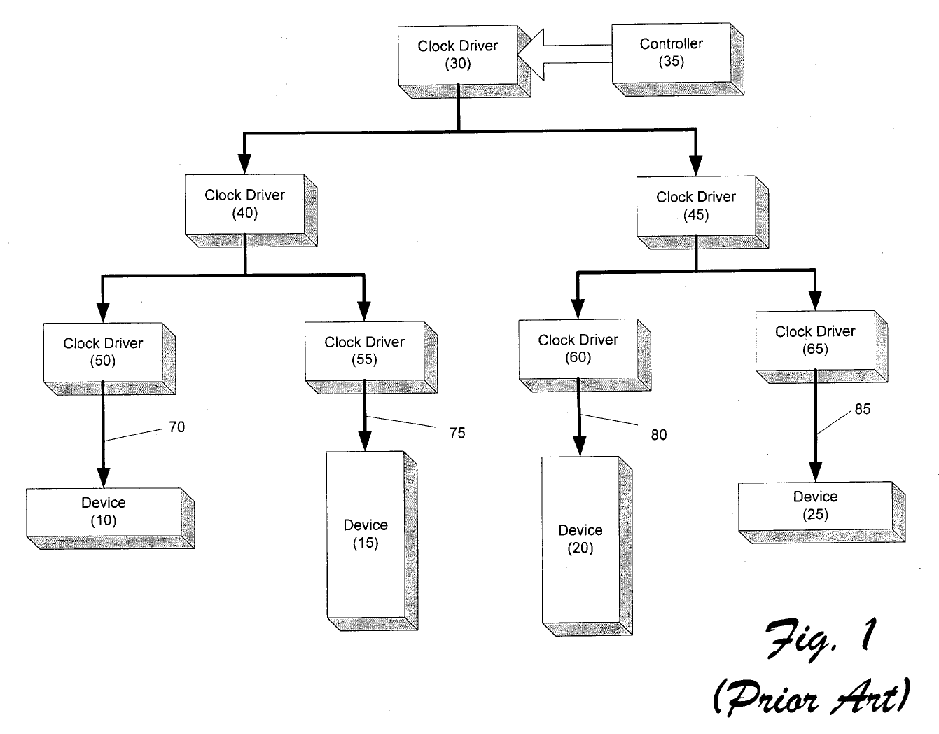

The respective bit registers of byte-word registers 200, 205, and 210 are physically positioned linearly next to one another (side by side). Therefore, a particular byte-word register has a first and a last bit register, along with a middle bit register or registers as determined from left to right. For example, byte-word register 200A has a first bit register 200A, a last bit register 200H, and middle bit registers 200D and 200E. Although the byte-word registers depicted in FIG. 1 are comprised of 8 bit registers, it should be understood that they byte-word registers may be comprised of fewer or more bit registers.

Byte-word registers 200, 205, and 210 and their respective bit registers are intended to be synchronized with one another. In other words, these components are intended to be synchronously clocked. To achieve this, component clock signals to each byte-word register are adjusted to have matching phases at the byte-word registers, after accounting for any differing propagation delays of the component clock signals.

The described embodiment includes a clock driver or a clock buffer that is able to store and provide a clock signal to a component or set of components. In this example separate clock drivers or clock buffers correspond to each set of components, which in this case equates to a separate clock driver or clock buffer for each respective byte-word register. Thus, a clock driver 215 provides a component or register clock signal 216 to byte-word register 200 and to bit registers 200A, 200B, 200C, 200D, 200E, 200F, 200G, and 200H. Component clock signal 216 travels along a path 217 from clock driver 215. Path 217 branches out to sub-paths 217A-H, which lead to individual bit registers 200A-H, respectively.

Similarly, a clock driver 220 provides a component or register clock signal 221 to byte-word register 205 and to bit registers 205A, 205B, 205C, 205D, 205E, 205F, 205G, and 205H. Component clock signal 221 travels along a path 222 from clock driver 220. Path 222 branches out to sub-paths 222A-H, which lead to individual bit registers 205A-H, respectively.

A clock driver 225 provides a component or register clock signal 226 to byte-word register 210 and to bit registers 210A, 210B, 210C, 210D, 210E, 210F, 210G, and 210H. Component clock signal 226 travels along a path 227 from clock driver 225. Path 227 branches out to sub-paths 227A-H, which lead to individual bit registers 210A-H, respectively.

In this example, clock drivers 215, 220, and 225 reside on the same IC as byte-word registers 200, 205, and 210. In other cases, clock drivers 215, 220, and 225 may reside on separate ICs. Clock drivers 215, 220, and 225 may receive input clock signals from a common source such as a clock tree. Such a clock tree architecture may be part of the same IC in which byte-word registers 200, 205, and 210 reside or be part of another IC.

In the case of a clock tree architecture, a master clock driver typically produces or drives a common clock signal that branches out to various clock drivers such as drivers 215, 220, and 225. In this example, clock drivers 215, 220, and 225 derive their respective component clock signals 216, 221, and 226 from the common clock signal produced within the clock tree architecture. Thus, each of the register clock signals is a variably-delayed version of the common clock signal.

Since clock signals 216, 221, and 226 originate from a common clock signal source, they have the same frequency. However, as clock signals 216, 221, and 226 travel across respective paths 217, 222, 229, and the sub-paths leading to individual bit registers, clock signals 216, 221, and 226 traverse potentially different distances. This results in differing propagation delays, which result in clock signals that are potentially out of phase with each other as they are received at the respective byte-word registers 210, 215, and 220. The clock drivers 215, 220, and 225 are capable of varying the phase of clock signals 216, 221, and 226 so that the phases of the clock signals 216, 221, and 226 are synchronized upon arrival at byte-word registers 200, 205, and 210.

A reference clock signal 230 is used to correct the phases of clock signals 216, 221, and 226, so that they are in phase with each other at the physical locations of the byte-word registers 210, 215, and 220. Reference clock signal 230 has the same frequency as clock signals 216, 221, and 226. Clock signal 230 may be generated by an arbitrary clock source; however, it is contemplated that reference clock signal 230 may be provided by or derived from the same clock tree or clock architecture from which component clock signals 216, 221, and 226 are derived. In certain cases, one of clock signals 216, 221, and 226 may be branched and used as reference clock signal 230. It is not necessary for reference clock signal 230 to have any particular phase relationship with the component clock signals 216, 221, and 227, although its phase preferably remains constant over time as compared to the component clock signals.

The described circuit has a reference line 231 comprising a source path 232 and a return path 233. Reference clock signal 230 propagates or travels from a sample or source point 235, along source path 236 to a reference or mid point 240, and back along return path 241 to a sample or return point 242. The lengths and corresponding propagation delays of source path 232 and return path 233 are approximately equal. In a preferred embodiment, the difference between the propagation delay along source path 232 (from sample point 235 to reference point 240) and the propagation delay along return path 233 (from sample point 242 to reference point 240) is less than 15%. One factor affecting the propagation delay of a signal along a path is the length of that path. In preferred embodiments, therefore, the length of source path 232 and return path 233 are substantially similar. The two paths 232 and 233 are preferably positioned adjacent or parallel to each other in order to ensure that their lengths and propagation delays are the same. In addition, the source and return paths are preferably routed to pass near or in close proximity to each of byte-word registers 200, 205, and 210.

Dashed vertical lines 244, 245, and 246 indicate points along the paths where the phases of reference clock signal 230 are evaluated. Dashed vertical lines 244, 245, and 246 do not represent actual parts of the circuit. These points are preferably selected to be in close proximity to the byte-word registers 200, 205, and 210. In other words, to optimize the effectiveness of the measurement, it is preferred that to locate the reference line 231 in close proximity to the byte-word registers 200, 205, and 210.

The purpose and nature of the phase evaluation will become more apparent as the discussion proceeds. Dashed vertical line 244 intersects reference line 231 at points 244 which includes a point 244A on the source path and point 244B on the return path 233. Dashed vertical line 245 intersects reference line 231 at points 245 which includes a point 245A on the source path 232 and point 245B on the return path 233. Dashed vertical line 246 intersects reference line 231 at points 246 which includes a point 246A on the source path 232 and point 246B on the return path 233.

The layout of reference line 231 is such that at any one of the points of intersection of the reference line 231 and respective dashed vertical lines 244, 245, and 246, the distance or propagation delay between that point and mid point 240 is substantially identical along both the source path and the return path. In a preferred embodiment, the difference in the propagation delay along the source path and the propagation delay along the return path is less than 15%.

For purposes of discussion, a clock edge is deemed to pass source point 235 at a start time to. The same clock edge passes mid point 240 at a middle time t_{M}. The same clock edge passes last point 242 at a return time t_{L}. The clock edge also passes intermediate points 244A, 245A, 246A, 246B, 245B, and 244A.

Mid point 240 is at the point where source path 232 meets return path 233 Thus, middle time t_{M} is equal to the average of t₀ and t_{L} or (t₀+t_{L})/2. Assuming for purposes of discussion that t₀=0 and the round-trip propagation time is 900 picoseconds, t_{L}=900 picoseconds and t_{M}=450 picoseconds.

Now assume for purposes of discussion that source path 232 and return path 233 are bisected at any arbitrary location, such as the location indicated by dashed line 247 in FIG. 2 (points 247A and 247B). A clock edge of reference clock signal 230 is propagated along source path 232. A first time value t₁ is defined as the propagation time of the clock edge along source path 232 from source point 235 to point 247A. A second time value t₂ is defined as the propagation time of the clock edge from point 247A along source path 232 to mid point 240, and back along return path 233 and to point 247B. An average time value t_{A} of the first and second time values t₁ and t₂ is calculated. Regardless where location 247 is placed along source path 232 and return path 233, the average time value t_{A} will have a value equal, to the midpoint time value (t₀+t_{L})/2, or 450 picoseconds in this example.

Source path 232 and return path 233 are laid out so that they pass in near proximity to byte-word registers 200, 205, and 210. In preferred embodiments, the source path 232 and return path 233 are routed to pass in near proximity to the middle bit registers of byte-word registers 200, 205, and 210. Performing a time or phase averaging of a reference clock signal as it passes on source path 232 and return path 233 at a physical location in near proximity to these bit registers results in a common value or phase at each of the three locations. Average time or phase determinations are performed at points 244A, 244B (corresponding to registers 200D, 200E); points 245A, 245B (corresponding to registers 205D, 205E); and points 246A, 246B (corresponding to registers 210D, 210E). In this particular example, the average time value t_{A} at each of these locations will be 450 picoseconds, relative to the time when the clock edge passes source point 235.

In this example, assume that the propagation times along the source path 232 are as follows: 100 picoseconds from source point 235 to intermediate point 244A (at register 200); 200 picoseconds from intermediate point 244A to intermediate point 245A (at register 205); 100 picoseconds from intermediate point 245A to intermediate point 246A (at register 210); and 50 picoseconds from intermediate point 246A to mid point 240A. The total propagation delay from source point 235 to mid point 240 is thus 450 picoseconds. Similarly, the propagation times along the return path 233 are as follows: 50 picoseconds from mid point 240 to intermediate point 246B (at register 210); 100 picoseconds from intermediate point 246B to intermediate point 245B (at register 205); 200 picoseconds from intermediate point 245B to intermediate point 244B (at register 200); and 100 picoseconds from intermediate point 244B to source point 243. The total propagation delay from mid point 235 to return point 242 is thus 450 picoseconds.

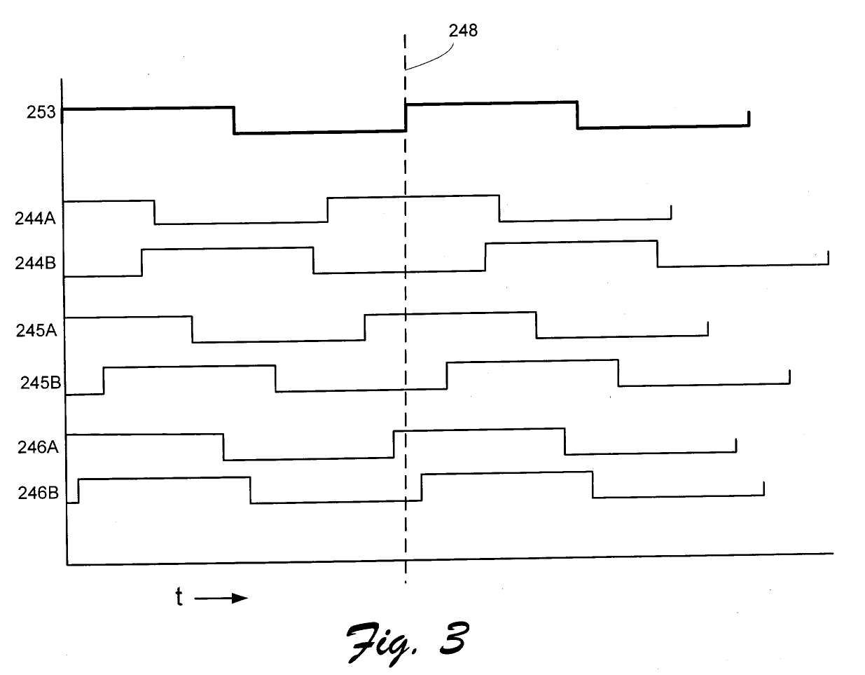

FIG. 3 shows the relative timing and phases of the synchronization signal on both the source path 232 and the return path 233 at each of locations 244A, 244B, 245A, 245B, 246A, and 246B. It is clear from this diagram that the average phase is the same at any given location along the reference line. A dashed vertical line 248 illustrates this midpoint or average time, relative to the rising edges of the reference clock signal on the source and return paths at each of locations 244A, 244B, 245A, 245B, 246A, and 246B. Also shown in FIG. 3 is an averaged phase clock signal 253 which represents a clock signal based on the average phases of the reference clock signal at each of the three locations. Averaged phase clock signal 253 has the same frequency as each of the other signals shown in FIG. 3, but has a phase equal to the average phase of the reference clock signal at each of points 244, 245, and 246.

Referring back to FIG. 2, a phase averager 255 is placed as close as is practical to the middle of bit registers 200D and 200E, corresponding in location to point 244 along reference line 231, which is also selected to be approximately at the middle of bit registers 200D and 200E. Phase averagers 256 and 257 are similarly configured at each of the registers 205 and 210.

Phase averager 255 receives and is responsive to the phases of reference clock signal 230 as evaluated at point 244A on source path 232 and point 244B on return path 233. Phase averager 255 evaluates or compares the phases of reference clock signal 230 at these points and in response produces an averaged phase clock signal 255A whose phase is approximately equal to the average phase of the reference clock signal at points 244A and 244B (as illustrated by trace 253 of FIG. 3). Averaged phase clock signal 255A is propagated along path 258.

Phase averager 256 receives and is responsive to the phase of reference clock signal 230 as received at point 245A on source path 232 and point 245B on return path 233. Phase averager 256 evaluates or compares the phases of reference clock signal 230 as received at points 245A and 245B, and in response produces an averaged phase clock signal 256A whose phase is approximately equal to the average phase of the reference clock signal at points 245A and 245B (as illustrated by trace 253 of FIG. 3). Average phase clock signal 256A is propagated along path 259.

Phase averager 257 receives and is responsive to the phase of reference clock signal 230 as received at point 246A on source path 232 and point 246B on return path 233. Phase averager 257 evaluates or compares the phases of reference clock signal 230 as received at points 246A and 246B, and in response produces an averaged phase clock signal 257A whose phase is approximately equal to the average phase of the reference clock signal at points 246A and 246B (as illustrated by trace 253 of FIG. 3). Average phase clock signal 257A is propagated along path 260. Various phase averager circuits, often referred to as phase mixers, are well known and often used for other purposes. A phase mixer might be implemented in analog or digital form

The circuit includes phase adjusters 265, 266, and 267 corresponding respectively to registers 200, 205, and 210. Each phase adjuster receives two periodic signals: (a) the averaged phase clock signal of the corresponding phase averager (b) the component clock signal received by the corresponding byte-word register. In a preferred embodiment, the component clock signal is routed to the phase adjuster along a path that originates near the byte-word register. In the described embodiment, the path originates at or near the middle of the register. The path is preferably positioned alongside the path of the averaged phase clock signal to the phase adjuster, so that both the component clock signal and the averaged clock signal are subject to similar or identical propagation delays as they travel from the register to the phase adjuster.

At each phase adjuster, any phase difference between the component clock signal and the averaged clock signal translated to an offset time value. This value is provided in a feedback loop to the corresponding clock driver, to adjust the phase of its output. This feedback loop is configured in such way to eventually reduce or minimize any difference between the component clock signal and the averaged clock signal.

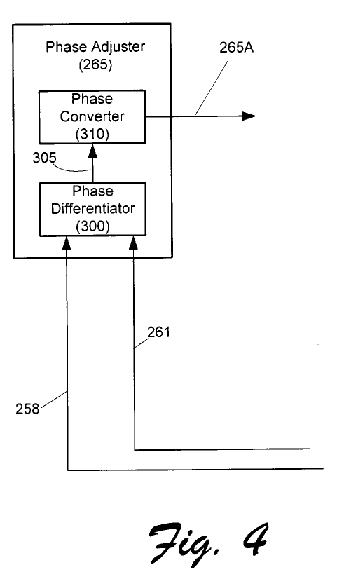

Referring now to FIG. 4, illustrated is an exemplary embodiment of phase adjuster 265. Phase adjusters 266 and 267 are similarly implemented. In this example, phase adjuster 265 includes phase differentiator 300 that determines the phase difference between average phase clock signal 255A and synchronized clock signal 216D. Phase differentiator 300 determines a phase value 305 that represents the amount of phase in which signals 255A and 216D differ. Phase value 305 is either an advance or delay time value. Phase converter 310 receives and converts phase value 305 to a time value offset value 265A. Time offset value 265A is provided to clock driver 215, which adjusts its output phase accordingly.

Referring back to FIG. 2, phase adjuster 265 receives average phase clock signal 255A by way of path 258 and synchronized clock signal 216 by way of path 217D further traveling by way of path 261. To reduce propagation phase delay differences between paths 258 and 261, such paths, in preferred embodiments, 1) have approximately the same length, 2) have similar impedance characteristics, and 3) are routed adjacent to each other. Phase adjuster 265 determines the phase difference between average phase clock signal 255A and synchronized clock signal 216D, and provides an adjusted time offset value 265A to clock driver 215. Adjusted time offset value 265A delays or advances synchronized clock signal 216 in relation to average phase clock signal 255A.

Phase adjuster 266 receives average phase clock signal 256A by way of path 259 and synchronized clock signal 221 by way of path 262. To reduce any propagation phase delay differences due to unequal length paths, paths 259 and 262 are approximately the same length, have similar impedance characteristics, and are routed adjacent to each other. Phase adjuster 266 determines the phase difference between average phase clock signal 256A and synchronized clock signal 221D, and provides an adjusted time offset value 266A to clock driver 220. Adjusted time offset value 266A delays or advances synchronized clock signal 221 in relation to average phase clock signal 256A.

Phase adjuster 267 receives average phase clock signal 257A by way of path 260 and synchronized clock signal 226 by way of path 263. To reduce any propagation phase delay differences due to unequal length paths, paths 260 and 263 are approximately the same length, have similar impedance characteristics, and are routed adjacent to each other. Phase adjuster 267 determines the phase difference between average phase clock signal 257A and synchronized clock signal 226D, and provides an adjusted time offset value 267A to clock driver 220. Adjusted time offset value 267A delays or advances synchronized clock signal 226 in relation to average phase clock signal 257A.

Digital signals may degrade over a path or bus. In order to avoid signal degradation, buffers or inverters 270A, 270B, 270C, 270D, 275A, 275B, 275C, 275D, 280A, 280B, 280C, and 280D may be placed along source bus line 236 and return bus line 241 at the locations of individual registers. The inverters are paired so that clock reference signal 230 is inverted immediately prior to arriving at the middle of each byte-word register and immediately re-inverted after leaving the middle of each byte-word register. This pairing may not be necessary if non-inverting buffers are used. In either case, because equal numbers of buffers or inverters are used symmetrically in the source and returns paths, the average phases of clock reference signal 230 are not affected.

Although details of specific implementations and embodiments are described above, such details are intended to satisfy statutory disclosure obligations rather than to limit the scope of the claims. Thus, the invention is not limited to the specific features described above.

1. A circuit comprising:
a first clock driver configured to provide a first clock signal having a first phase at a first component;
a reference clock line configured to allow propagation of a reference clock signal, wherein the reference clock signal has a first reference phase at a first location on the reference clock line and a second reference phase at a second location on the reference clock line;
a phase averager configured to determine an average reference phase by averaging the first and second reference phases; and
a phase adjuster configured to adjust the first phase in response to the average reference phase.

2. The circuit of claim 1 wherein a propagation delay from the first location to a reference point on the reference clock line is substantially equal to a propagation delay from the second location to the reference point.

3. The circuit of claim 2 wherein the first location and the second location are substantially equidistant from the reference.

4. The circuit of claim 1 further comprising a second clock driver configured to provide a second clock signal having a second phase at a second component;
a second phase average configured to determine a second average reference phase by averaging a third reference phase measured at a third location on the reference clock line and a fourth reference phase measured at a fourth location on the reference clock line; and
a second phase adjuster configured to adjust the second phase in response to the second average reference phase.

5. The circuit of claim 4 wherein the first and second average reference phases are substantially similar.

6. The circuit of claim 4 wherein a propagation delay from the first location to the reference point is substantially equal to a propagation delay from the second location to the reference point.

7. The circuit of claim 6 wherein the first and second locations are substantially equidistant from the reference point and the third and fourth locations are substantially equidistant from the reference point.

8. The circuit of claim 4, wherein each phase adjuster is configured to determine a phase offset value; and the clock drivers are responsive to the phase offset values to adjust the phases of the first and second clock signals.

9. The circuit of claim 4, wherein the clock drivers derive the first and second clock signals from a common clock signal.

10. The circuit of claim 1 further comprising a second clock driver configured to provide a second clock signal having a second phase at a second component;
a phase adjuster configured to adjust the first phase in response to the average reference phase and adjust the second phase in response to the phase at a reference point.

11. The circuit of claim 10 wherein the phase adjuster comprises a first phase adjuster to adjust the first phase and a second phase adjuster to adjust the second phase.

12. A method of synchronizing clock signals comprising:
generating a first clock signal, wherein the first clock signal has a first phase at a first component, a second clock signal, wherein the second lock signal has a second phase at a second component, and a reference clock signal, wherein the reference clock signal has a first reference phase at a first location on a reference clock line and a second reference phase at a second location on the reference clock line;
determining the first reference phase and second reference phase;
determining an average reference phase by averaging the first and second reference phases; and
adjusting the first phase and the second phase to the average reference phase.

13. The method of claim 12 wherein first and locations are substantially equidistant from a reference point on the reference line.

14. A method of synchronizing clock signals comprising:
generating a first clock signal, wherein the first clock signal has a first phase at a first component, a second clock signal, wherein the second clock signal has a second phase at a second component, and a reference clock signal, wherein the reference clock signal has a first reference phase at a first location on a reference clock line, a second reference phase at a second location on the reference clock line, a third reference phase at a third location of the reference clock line, and a fourth reference phase at a fourth location of the reference clock line, and wherein propagation delays are substantially equal from the first location to a reference point and the second location to the reference point, and propagation delays are substantially equal from the third location to the reference point and the fourth location to the reference point;
determining the first, second, third, and fourth reference phases;
determining a first average reference phase by averaging the first and second reference phases;
determining a second average reference phase by averaging the third and fourth reference phases;
adjusting the first phase to more closely match the first average reference phase; and
adjusting the second phase to more closely match the second average reference phase.

15. A circuit comprising:
a plurality of clock drivers, wherein the clock drivers are configured to provide separate component clock signals to corresponding components by way of separate paths;
a reference line comprising source and return paths, wherein a reference clock signal propagates first along the source path and then back along the return path; and
phase averagers corresponding respectively to components, each phase averager being configured to average phases of the reference clock signal on the source and return paths; and
wherein the clock drivers are responsive to the phase averagers to adjust the phases of the component clock signals.

16. The circuit of claim 15, wherein the phase averagers comprise
a first phase averager corresponding to one of the components, the first phase averager is configured to average a first and second phase of the reference clock, and wherein the first phase is measured at a first location on the reference clock line and the second phase is measured at a second location on the reference clock line and wherein the first and second locations are equidistance from a reference point of the reference line; and
a second phase averager corresponding to another one of the components and wherein the second phase averager is configured to average a third and forth phase of the reference clock, wherein the third phase is measured at a third location on the reference clock line and the forth phase is measured at a forth location on the reference clock line and wherein the third and forth locations are equidistance from the reference point of the reference line.

17. The circuit of claim 15 wherein
a propagation delay along the source path, from the first location to the reference point, is substantially equal to a propagation delay along the return path, from the second location to the reference point; and
a propagation delay along the source path, from the third location to the reference point, is substantially equal to a propagation delay along the return path, from the forth location to the reference point.

18. The circuit of claim 16 wherein
the first and second locations are substantially equidistant from the reference point, and
the third and forth locations are substantially equidistant from the reference point.

19. The circuit of claim 16, wherein the reference clock line is adjacent to the components.

20. The circuit of claim 16, further comprising phase adjusters corresponding respectively to the components, wherein each phase adjuster is responsive to one of the phase averagers to determine a phase offset value; and wherein the clock drivers are responsive to the phase offset values to adjust the phases of the component clock signals.

21. A method of synchronous clocking, comprising:
routing individual component clock signals to corresponding components along separate paths that potentially have different propagation delays;
propagating a reference clock signal along a source path and then back along a return path;
for each component, generating an averaged phase signal whose phase is an average of a first phase of the reference clock signal at a first location on the source path and a second phase of the reference clock signal at a second location on the return path; and
adjusting the phase of one or more of the individual component clock signals based on the averaged phase signals to reduce phase differences in the component clock signals at the respective component.

22. The method of claim 21, wherein for each component, a propagation delay along the source path from the first location to a reference location on the reference clock line is substantially similar to a propagation delay along the return path from the second location to the reference location.

23. The method of claim 22, wherein for each component, a length of the source path from the first location to the reference location is substantially equal to a length of the return path from the second location to the reference location.

24. One or more components comprising:
means for routing individual component clock signals to corresponding components along separate paths that potentially have different propagation delays;
means for propagating a reference clock signal along a source path and then back along a return path;
means for generating an averaged phase signal at each particular components, wherein the phase of the averaged phase signal is an average of the reference clock signal on the source and return paths at the particular components; and
means for adjusting the phases of the component clock signals to reduce phase differences in the average phase signal and the component clock signal at any given component.

25. A component as recited in claim 24, wherein the means for generating an averaged phase signal are positioned respectively at the component.

26. A component as recited in claim 24, wherein a propagation delay along the source is substantially equal to a propagation delay along the return path.

27. A component as recited in claim 26, wherein the lengths of the source and return paths are substantially equal.

28. A component as recited in claim 24, wherein each means for adjusting the phases is responsive to (a) an averaged clock signal from a corresponding one of the means for generating and (b) one of the component clock signals.
